(19) United States
(12) Patent Application Publication
(10) Pub. No.: US 2007/0193515 A1
(43) Pub. Date: Aug. 23, 2007

(54) Apparatus for generating remote plasma

(75) Inventors: Hyeong-Tag Jeon, Seoul (KR); In-Hoe Kim, Seoul (KR); Seok-Hoon Kim, Incheon (KR); Chin-Wook Chung, Seoul (KR); Sahng-Kyoo Lee, Ansan (KR)

Correspondence Address: HEDMAN & COSTIGAN P.C., 1185 AVENUE OF THE AMERICAS, NEW YORK, NY, 10036, US

(73) Assignee: Industry-University Cooperation Foundation Hanyang University, Seoul (KR)

(21) Appl. No.: 11/703,621

(22) Filed: Feb. 7, 2007

(30) Foreign Application Priority Data
Feb. 17, 2006 (KR) 2006/15759

(51) Int. Cl. C23F 1/00; C23C 16/00

(52) U.S. Cl. 118/723 IR; 156/345.48

(57) ABSTRACT

Provided is an apparatus for generating remote plasma. The apparatus includes an RF antenna disposed in regard to a chamber, a plasma generating unit formed in an uppermost portion of the chamber, wherein a plurality of plasma generation gas introduction pipes are communicated with the plasma generating unit, a first shower head disposed below the plasma generating unit, and having a plurality of first plasma guide holes, a second shower head disposed below the first shower head, and having a plurality of source/purge gas guide holes and a plurality of second plasma guide holes directly connected to the respective first plasma guide holes, and a source/purge gas introduction unit disposed between the first and second shower heads, wherein a plurality of source/purge gas introduction pipes are uniformly communicated with the source/purge gas introduction unit.

### BACKGROUND ART

1. Field of the Invention

The present invention relates to an apparatus for generating remote plasma, and more particularly, to an apparatus for generating remote plasma that improves uniformity and quality of a thin film.

2. Description of the Related Art

In recent years, as semiconductor devices shrink in size, it is required to perform plasma treatment under higher vacuum state for realizing a pattern or the like with high aspect ratio in dry etching, and filling a filling material into a hole or the like with high aspect ratio in plasma chemical vapor deposition (CVD) and atomic layer deposition (ALD).

In a typical parallel plate type plasma generator, a substrate electrode on which a substrate is mounted and an opposite electrode are disposed in a vacuum chamber, and a high frequency voltage is then applied between the substrate electrode and the opposite electrode using high frequency power for electrode. Thus, plasma is generated in the vacuum chamber.

However, according to the above constitution, the generated plasma does not uniformly react with the substrate mounted in the chamber so that it is difficult to form a thin film uniformly.

Moreover, ions, e.g., particularly, positive ions, generated at a plasma generating unit are supplied without any control, which leads to a problem that the substrate or the thin film is damaged.

### SUMMARY OF THE INVENTION

An object of the present invention is to provide an apparatus for generating remote plasma that can supply plasma generation gas to a substrate uniformly to improve a uniformity of a thin film.

Another object of the present invention is to provide an apparatus for generating remote plasma that can appropriately control positive ions generated with plasma to improve a quality of a thin film.

According to an aspect of the present invention, there is provided an apparatus for generating a remote plasma, including: an RF (radio frequency) antenna disposed in regard to a chamber; a plasma generating unit formed in an uppermost portion of the chamber, wherein a plurality of plasma generation gas introduction pipes are communicated with the plasma generating unit; a first shower head disposed below the plasma generating unit, and having a plurality of first plasma guide holes; a second shower head disposed below the first shower head, and having a plurality of source/purge gas guide holes and a plurality of second plasma guide holes directly connected to the respective first plasma guide holes; and a source/purge gas introduction unit disposed between the first and second shower heads, wherein a plurality of source/purge gas introduction pipes are uniformly communicated with the source/purge gas introduction unit.

The apparatus may further include a DC bias generating unit disposed between the plasma generating unit and the first shower head. The DC bias generating unit may have the shape of a grid, and may be formed of metallic material of which a surface is anodized.

An inlet and an outlet of each of the first plasma, second plasma and source/purge gas guide holes, and an outlet of each of the plasma generation gas and source/purge gas introduction pipes may be tapered such that its diameter becomes greater as it gets closer to an end thereof.

The first plasma guide holes may be radially arranged in the first shower head, and the second plasma guide holes and the source/purge gas guide holes may be radially and alternately arranged in the second shower head.

The plurality of plasma generation gas introduction pipes may be communicated with the plasma generating unit through an upper portion thereof or a side portion thereof.

### BRIEF DESCRIPTION OF THE DRAWINGS

The above objects and other advantages of the present invention will become more apparent by describing in detail preferred embodiments thereof with reference to the attached drawings in which:

FIG. 1 is a sectional view of an apparatus for generating remote plasma according to one embodiment of the present invention;

FIGS. 2A and 2B are plan views illustrating the apparatus for generating the remote plasma of FIG. 1;

FIG. 3A is a sectional view taken along line 3a-3a of FIG. 1, and FIG. 3B is a sectional view taken along line 3b-3b of FIG. 1;

FIG. 4 is a sectional view illustrating a modified shape of a plasma guide pipe;

FIG. 5 is a schematic view of a DC bias generating unit;

FIG. 6 is a schematic view illustrating one example of an RF antenna; and

FIG. 7 is a sectional view of an apparatus for generating remote plasma according to another embodiment of the present invention.

### DETAILED DESCRIPTION OF THE PREFERRED EMBODIMENT

Now, preferred embodiments of the present invention will be described in detail with reference to the accompanying drawings.

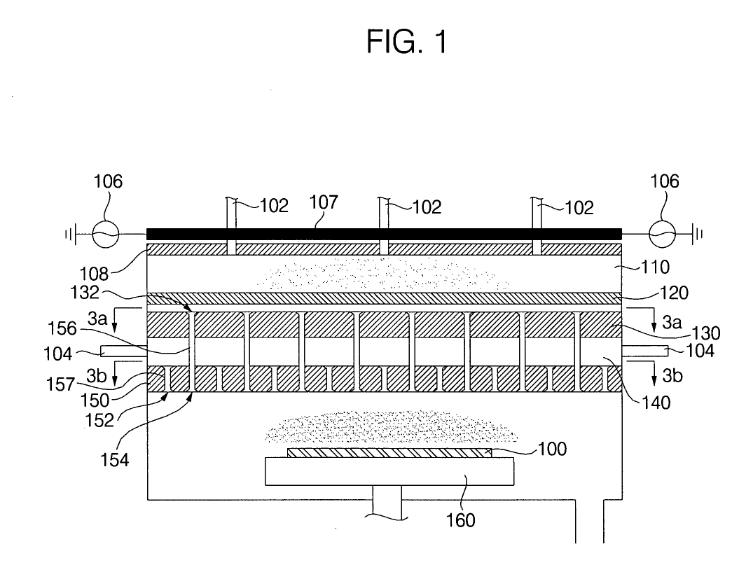

FIG. 1 is a sectional view of an apparatus for generating remote plasma according to one embodiment of the present invention;

An apparatus for generating remote plasma includes a radio frequency (RF) antenna, a plasma generating unit 120, a first shower head 130, a source/purge gas introduction unit 140, and a second shower head 150.

The RF antenna 107 is disposed over an insulating member 108 such as quartz of a chamber, and plays a role in generating plasma. The RF antenna 107 may be configured such that plasma can be uniformly generated.

Specifically, referring to FIG. 6, at least two loop-type antenna elements 10 and 20 are horizontally spaced apart from each other by a predetermined distance such that they are overlapped with each other. The two loop-type antenna elements 10 and 20 are electrically connected in parallel. Herein, a power supply terminal P and a ground terminal G are formed at one end and the other end of each of the loop-type antenna elements 10 and 20, respectively. The power supply terminal P and the ground terminal G are disposed symmetrically with respect to a center of each of the antennal elements 10 and 20. A horizontally bent portion 10a of the antenna element 10 is disposed between the power supply and ground terminals P and G of the other antenna element 20. Likewise, a horizontally bent portion 20a of the antenna element 20 is disposed between the power supply and ground terminals P and G of the other antenna element 10.

A total impedance of the antenna is lowered because the antenna elements 10 and 20 are electrically connected in parallel, and thus it is possible to apply a low voltage. The horizontally bent portions 10a and 20a play a role in complementing disconnected portions between the power supply terminal P and the ground terminal G. Accordingly, an antenna current is not cut off but is continued. In addition, there is no electric field difference because the bent portions 10a and 20a are horizontally bent at a central portion of each antenna element, which makes it possible to distribute plasma uniformly.

A plasma generating unit 110 is formed in an upper portion of the chamber, and is isolated from an exterior by means of the insulating member 108 such as quartz.

According to the present invention, a plurality of plasma generation gas introduction pipes 102 are communicated with the plasma generating unit 110 uniformly. This means that portions where the plasma generation gas introduction pipes 102 are communicated with the plasma generating unit 110 are uniformly arranged.

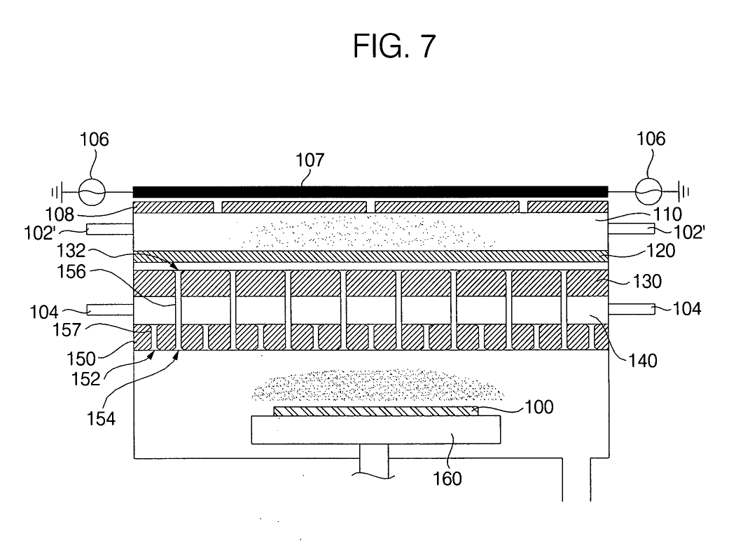

In one embodiment, the plurality of plasma generation gas introduction pipes 102 are communicated with the plasma generating unit 110 through an upper portion of the plasma generating unit 110. According to another embodiment of FIG. 7, however, the plurality of plasma generation gas introduction pipes 102 are communicated with the plasma generating unit 110 through a side portion of the plasma generating unit 110.

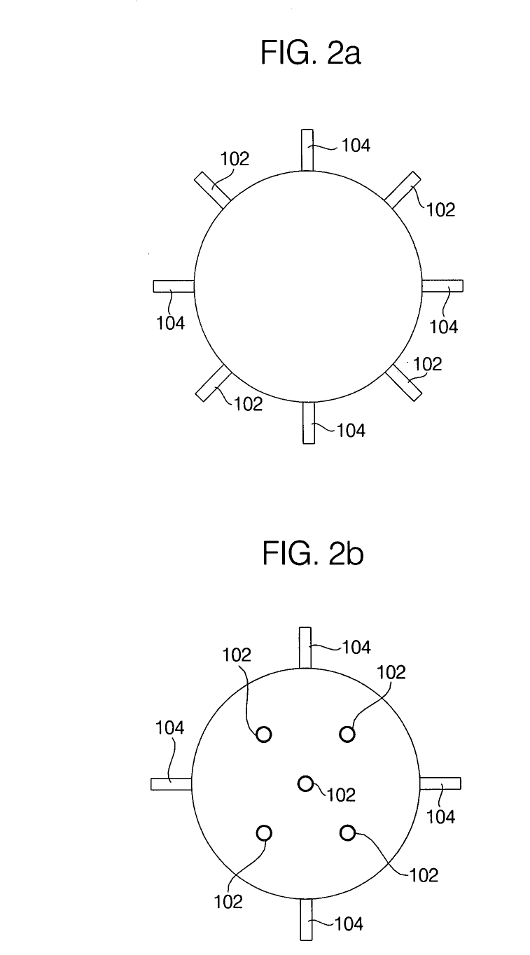

In one embodiment, the plurality of plasma generation gas introduction pipes 102 are uniformly arranged on an entire surface as illustrated in FIG. 2A. In another embodiment, the plurality of plasma generation gas introduction pipes 102 are disposed on a side portion such that they are separated from each other at a predetermined rotation angle, as illustrated in FIG. 2B.

Although the number of the plurality of plasma generation gas introduction pipes 102 is 5 and 4 in FIGS. 2A and 2B, respectively, the number of the plurality of plasma generation gas introduction pipes 102 is not limited to it.

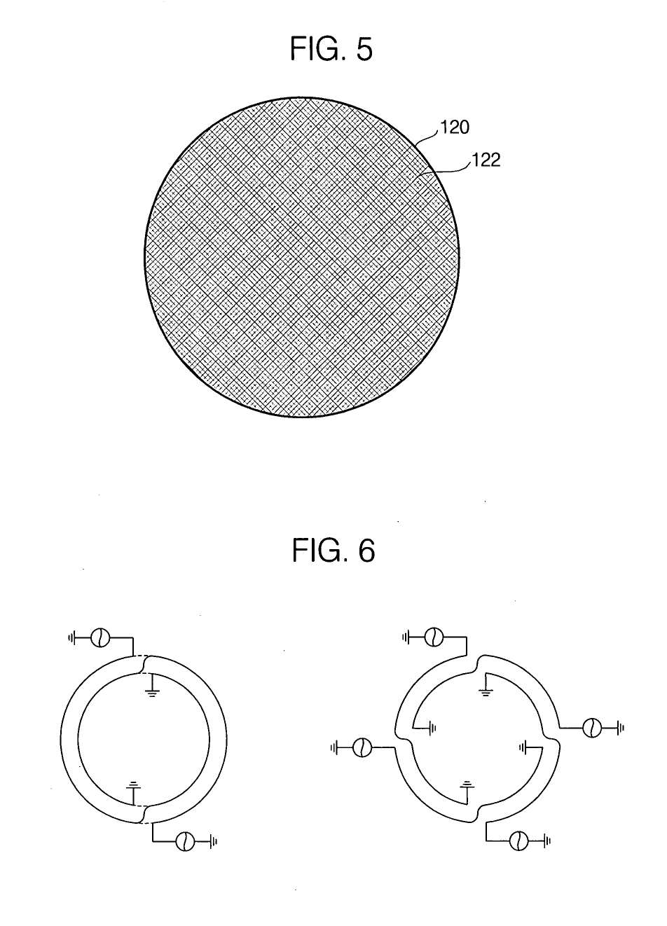

The DC bias generating unit 120 is disposed under the plasma generating unit 110. Referring to FIG. 5, preferably, the DC bias generating unit 120 has the shape of a grid 122 such that plasma passes therethrough. In addition, the DC bias generating unit 120 is formed of metallic material, and its surface is anodized.

In virtue of such a constitution, it is possible to prevent the damage of the substrate or the thin film, which may be caused by the trapping of the ions, i.e., positive ions, generated with plasma. Furthermore, since the surface of the DC bias generating unit 120 is anodized, it is possible to prevent contamination due to metallic impurities during the generation of plasma.

Below the DC bias generating unit 120, the first shower head 130 is disposed in which a plurality of first plasma guide holes 132 are formed.

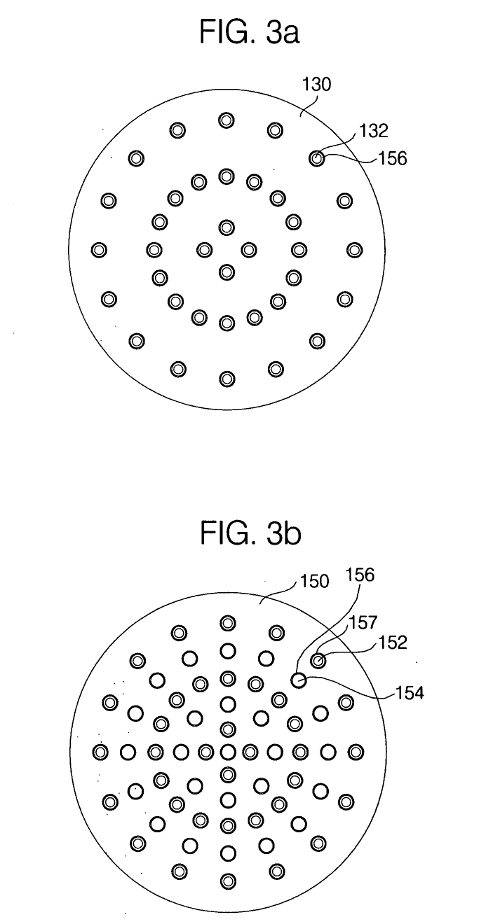

Referring to FIG. 3A, the plurality of first plasma guide holes 132 may be radially formed. As it will be described later, a plasma guide pipe 156 may be inserted into the first plasma guide hole 132, wherein the plasma guide pipe 156 is connected from the first plasma guide hole to a second plasma guide hole 154.

A source/purge gas introduction unit 140 is formed between the first shower head 130 and the second shower head 150. A plurality of source/purge gas introduction pipes 104 are disposed on side portions of the source/purge gas introduction unit 140 such that they are communicated with the source/purge gas introduction unit 140.

Referring to FIG. 3B, second plasma guide holes 154 and source/purge gas guide holes 152 are radially and alternately disposed in the second shower head 150, respectively.

Referring again to FIG. 2B, the plurality of source/purge gas introduction pipes 104 are disposed such that they are spaced apart from each other at a predetermined rotation angle.

A source/purge gas guide pipe 157 may be inserted into the source/purge gas guide hole 152. As described above, the plasma guide pipe 156 extends from the first shower head 130 to the second shower head 150 through the source/purge gas introduction unit 140.

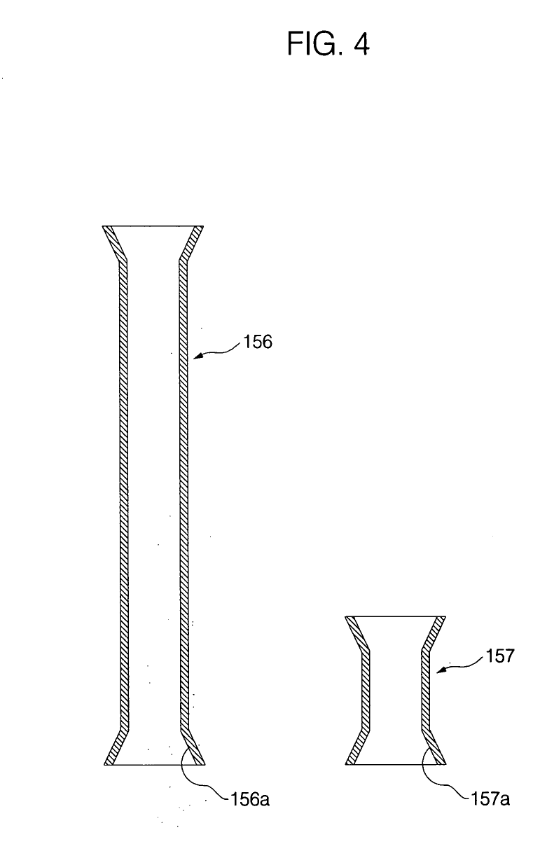

Referring to FIG. 4, the plasma guide pipe 156 has an inlet and an outlet of which each one may have tapered sidewalls 156a and 157a such that its diameter becomes greater as it gets closer to an end thereof.

According to this constitution, it is advantageous in that it is possible to uniformly spray gas onto a much wider area.

This constitution can also be identically applied to outlets of the plasma generation gas introduction pipe 102 and the source/purge gas introduction pipe 104.

According to such a constitution, uniform plasma is generated by means of plasma generation gas supplied through the plurality of plasma generation gas introduction pipes, and then is provided to the substrate through the plurality of plasma guide holes. At the same time, source/purge gas supplied through the plurality of source/purge gas introduction pipe is provided to the substrate through a plurality of source/purge gas introduction hole, and thus it is possible to form the thin film uniformly.

In addition, since the damage of the substrate and the thin film can be prevented by reliably trapping the positive ions generated with plasma in virtue of the DC bias generating unit, it is possible to improve the quality of the thin film.

Furthermore, it is possible to spray gas onto a much wider area because the inlet and outlet of each of the plasma and source/purge guide pipes are tapered such that a diameter of each of the inlet and the outlet becomes greater as it gets closer to an end thereof.

As described above, according to the present invention, plasma generation gas is supplied to a substrate uniformly, whereby the uniformity of the thin film can be enhanced.

In addition, the quality of the thin film can be enhanced by appropriately controlling positive ions generated with plasma.

While the present invention has been described in detail, it should be understood that various changes, substitutions and alterations can be made hereto without departing from the spirit and scope of the invention as defined by the appended claims.

What is claimed is:

1. An apparatus for generating a remote plasma, comprising:
an RF (radio frequency) antenna disposed in regard to a chamber;
a plasma generating unit formed in an uppermost portion of the chamber, wherein a plurality of plasma generation gas introduction pipes are communicated with the plasma generating unit;
a first shower head disposed below the plasma generating unit, and including a plurality of first plasma guide holes;
a second shower head disposed below the first shower head, and including a plurality of source/purge gas guide holes and a plurality of second plasma guide holes directly connected to the respective first plasma guide holes; and
a source/purge gas introduction unit disposed between the first and second shower heads, wherein a plurality of source/purge gas introduction pipes are uniformly communicated with the source/purge gas introduction unit.

2. The apparatus of claim 1, further comprising a DC bias generating unit disposed between the plasma generating unit and the first shower head.

3. The apparatus of claim 2, wherein the DC bias generating unit has the shape of a grid, and is formed of metallic material of which a surface is anodized.

4. The apparatus of claim 1, wherein an inlet and an outlet of each of the first plasma, second plasma and source/purge gas guide holes, and an outlet of each of the plasma generation gas and source/purge gas introduction pipes are tapered such that its diameter becomes greater as it gets closer to an end thereof.

5. The apparatus of claim 1, wherein the first plasma guide holes are radially arranged in the first shower head, and the second plasma guide holes and the source/purge gas guide holes are radially and alternately arranged in the second shower head.

6. The apparatus of claim 1, wherein the plurality of plasma generation gas introduction pipes are communicated with the plasma generating unit through an upper portion thereof or a side portion thereof.

7. The apparatus of claim 1, wherein a quartz is interposed between the RF antenna and the plasma generating unit.

8. The apparatus of claim 1, wherein the RF antenna comprises at least two loop-type antenna elements electrically connected in parallel and horizontally spaced apart from each other by a predetermined distance such that they are overlapped with each other, a power supply terminal being formed at one end and a ground terminal being formed at the other end of each of the antenna elements,
wherein the power supply terminal and the ground terminal of each of the antenna elements are symmetrically disposed with respect to a center of the antenna element, and a horizontally bent portion of one antenna element is disposed between the power terminal and the ground terminal of the other antenna element.
